(19) United States
(12) Patent Application Publication
(10) Pub. No.: US 2015/0182021 A1
(43) Pub. Date: Jul. 2, 2015

(54) TELEVISION CABINET

(71) Applicant: Chien-Kuo Chang, Taichung City (TW)

(72) Inventor: Chien-Kuo Chang, Taichung City (TW)

(21) Appl. No.: 14/141,293

(22) Filed: Dec. 26, 2013

(51) Int. Cl. A47B 81/06; A47B 43/00; A47B 96/00; H05K 5/00; H05K 5/02

(52) U.S. Cl. CPC A47B 81/06; H05K 5/0017; H05K 5/0217; A47B 96/00; A47B 43/00

(57) ABSTRACT

A television cabinet includes a front board, a rear board, at least two active boards, two side boards, and a top board. Therein, the active boards are hinged between the front board and the rear board, while each active board comprises a first panel and a second panel hinged together for enabling the front board and the rear board to move between a folded position and an unfolded position. The side boards are slidingly disposed between the front board and the rear board at the unfolded position. The top board is combined to the front board, the rear board, and the two side boards as a plane on top at the unfolded position. Therefore, the cost and inconvenience of transportation are lowered.

### BACKGROUND OF THE INVENTION

1. Field of the Invention

The present invention relates to television cabinets, and more particularly, to a foldable television cabinet which decreases the volume of the cabinet during transportation.

2. Description of the Related Art

Cabinets in a variety of kinds exist in the market nowadays, such as a television cabinet for bearing a television. However, ordinary television cabinets are structurally assembled by nails, screws, or welding, whereby dismantling such television cabinets for transportation is relatively difficult. As a result, the cabinets shall be transported with the maximum volume, which causes inconvenience and higher cost of transportation.

To resolve such disadvantages, manufacturers of television cabinets developed knock-down television cabinets for facilitating the transportation. However, if components of such television cabinets cannot be easily assembled or dismantled, a manual with complex instruction is still needed to facilitate the assembling. Therefore, such products still lack for convenience of installation for consumers with lower spacial and structural concept.

### SUMMARY OF THE INVENTION

For improving such difficulties, the present invention discloses a television cabinet, which is capable of being folded and unfolded, whereby the volume of the television cabinet is lowered during transportation, and easiness for assembling when being installed is assured.

The present invention provides a television cabinet, comprising:

a front board;

a rear board;

at least two active boards, hinged between the front board and the rear board, while each of the two active boards comprises a first panel and a second panel hinged together, respectively, for enabling the front board and the rear board to move between a folded position and an unfolded position;

two side boards, slidingly disposed between the front board and the rear board at the unfolded position; and

a top board, combined to the front board, the rear board, and the two side boards as a plane on top at the unfolded position.

With such structures, the volume of the television cabinet during transportation is decreased, whereby the cost and difficulty of transportation is lowered, and the television cabinet is allowed to be unfolded easily, providing convenience of installation.

Preferably, the first panel and the second panel of the present invention are hinged together for enabling the active board to be folded and unfolded.

Preferably, the active boards of the present invention are hinged with the front board and the rear board by hinges.

### BRIEF DESCRIPTION OF THE DRAWINGS

FIG. 1 is a perspective view of the television cabinet in accordance with the present invention.

FIG. 2 is an exploded view of the television cabinet in accordance with the present invention.

FIG. 3 is another exploded view of the television cabinet in accordance with the present invention.

FIG. 4 is a schematic view illustrating the installed status of the side board in accordance with the present invention.

FIG. 5 is a partially enlarged view of FIG. 4.

FIG. 6 is a schematic view illustrating the folding method of the television cabinet in accordance with the present invention.

FIG. 7 is a schematic view illustrating the folded status of the television cabinet in accordance with the present invention.

### DETAILED DESCRIPTION OF THE INVENTION

Other and further advantages and features of the present invention will be understood by reference to the description of the preferred embodiment in conjunction with the accompanying drawings where the components are illustrated based on a proportion for explanation but not subject to the actual component proportion.

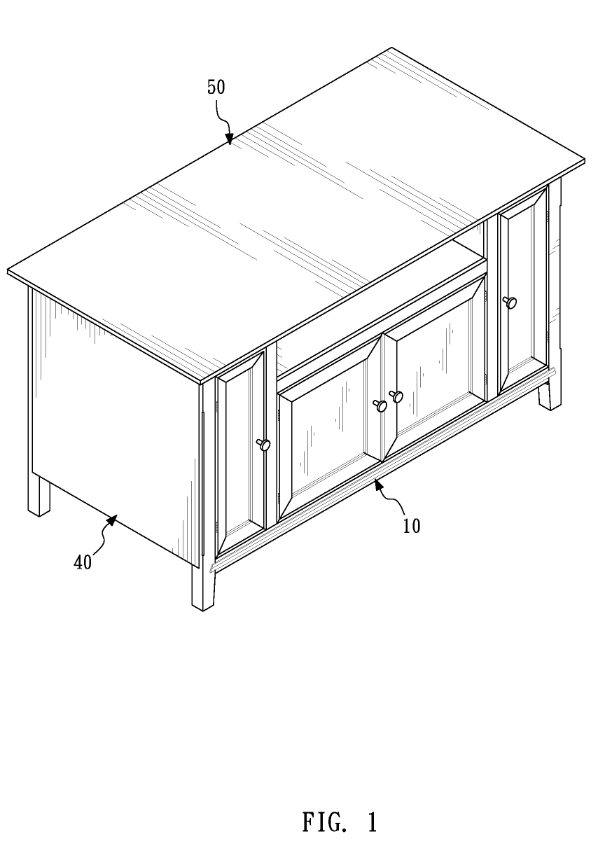

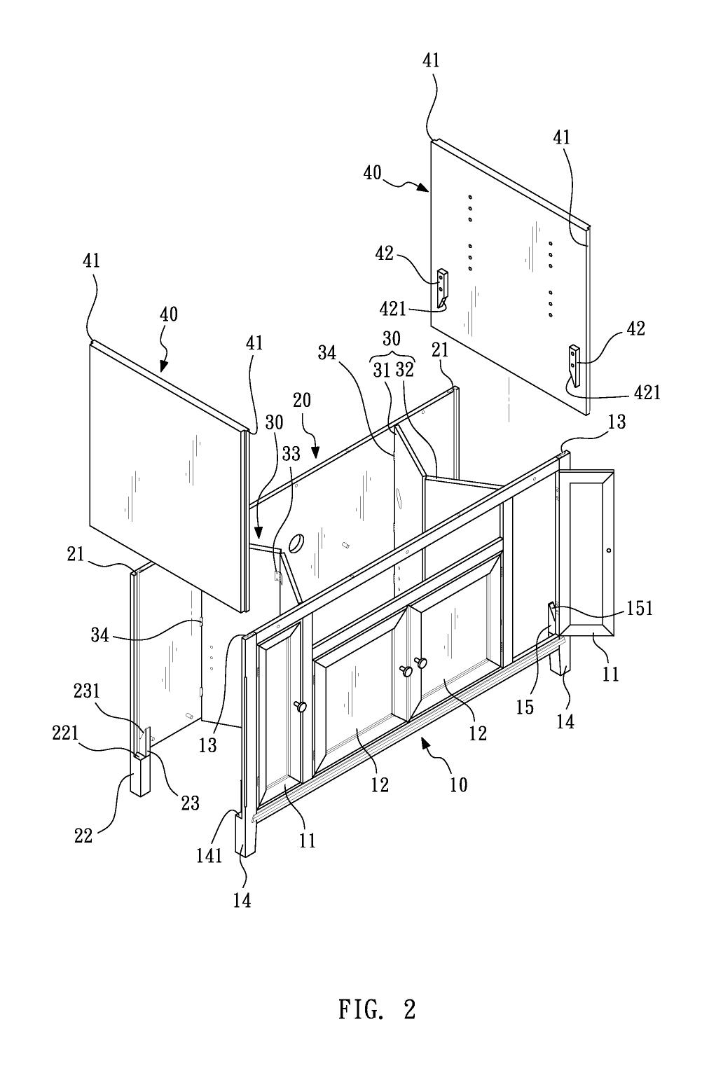

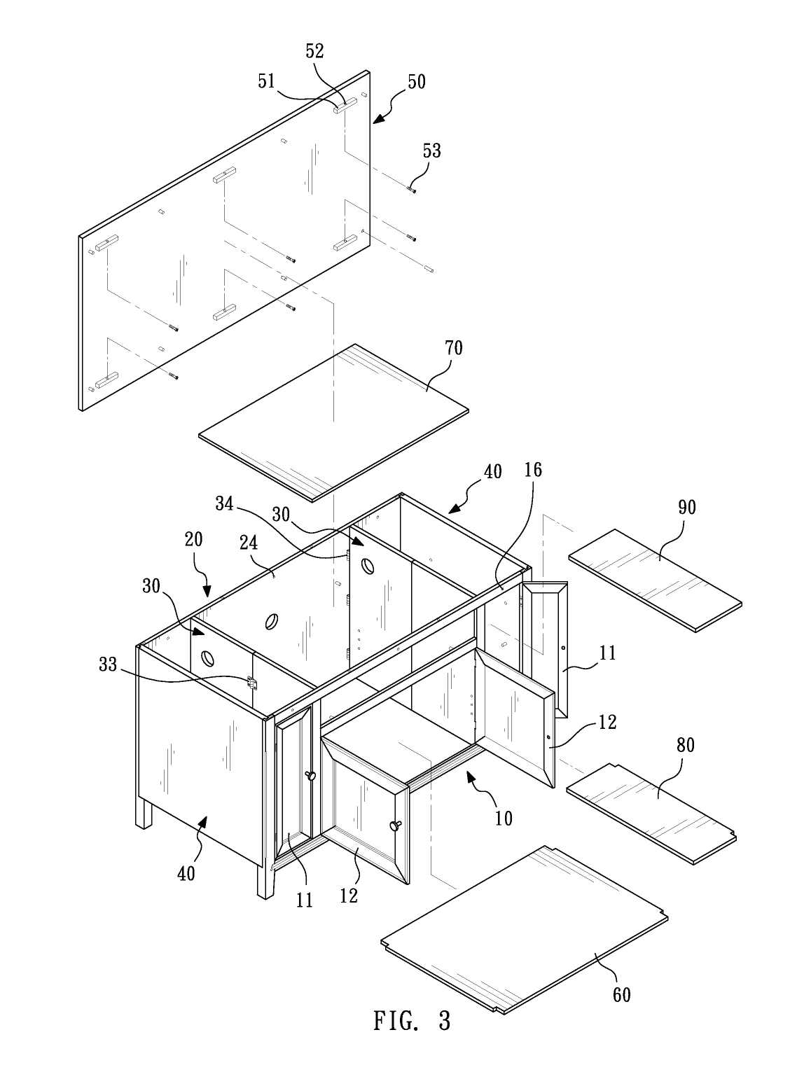

Referring to FIG. 1 to FIG. 3, a television cabinet 100 of the present invention comprises a front board 10, a rear board 20, at least two active boards 30, two side boards 40, and a top board 50.

The front board 10 is a hollow frame board, comprising plural doors capable of open or close against the front board 10, wherein the doors include two side doors 11 and two short doors 12 disposed between the two side doors 11. Inner surfaces of the two ends of the front board 10 are disposed with a strip-shaped rail 13, respectively. A foot 14 is disposed on a lower distal end of the rail 13, and a holding surface 141 is disposed on the foot 14. Furthermore, a supporter 15 with a bevel 151 thereon is fixed adjacent to the holding surface 141.

The rear board 20 is provided with a strip-shaped rail 21 on inner surfaces of two ends thereof, respectively. A foot 22 is disposed on a lower distal end of the rail 21, and a holding surface 221 is disposed on the foot 22. Furthermore, a supporter 23 with a bevel 231 thereon is fixed adjacent to the holding surface 221.

Each of the two active boards 30 comprises a first panel 31 and a second panel 32 hinged together by plural hinges 33, whereby the first and second panels 31, 32 are allowed to pivot open and close against each other; also, the first and second panels 31, 32 are hinged to the front and the rear boards 10, 20 by plural hinges 34, respectively, whereby the two active boards 30 are disposed between the front board 10 and the rear board 20. Therefore, the front board 10 and the rear board 20 are allowed to move between a folded position and an unfolded position.

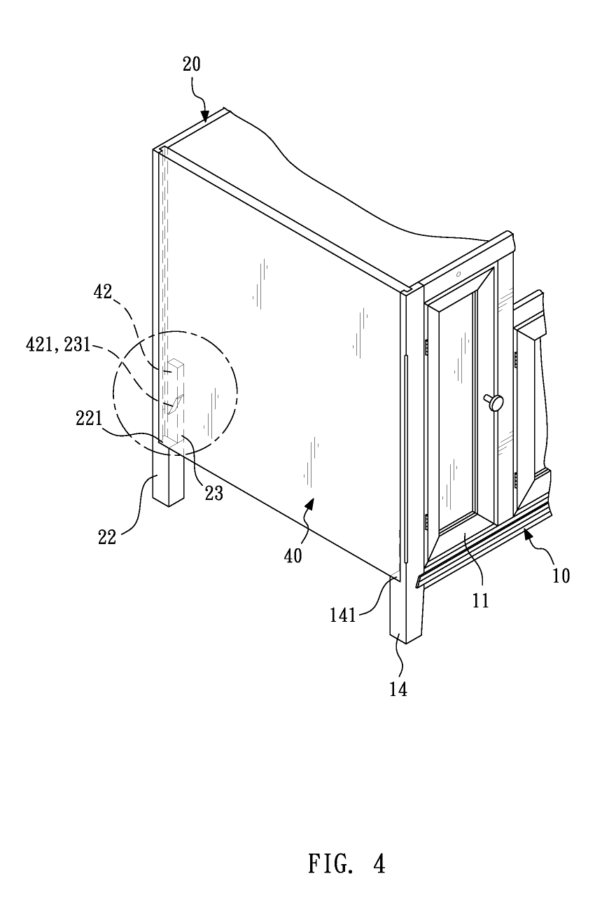

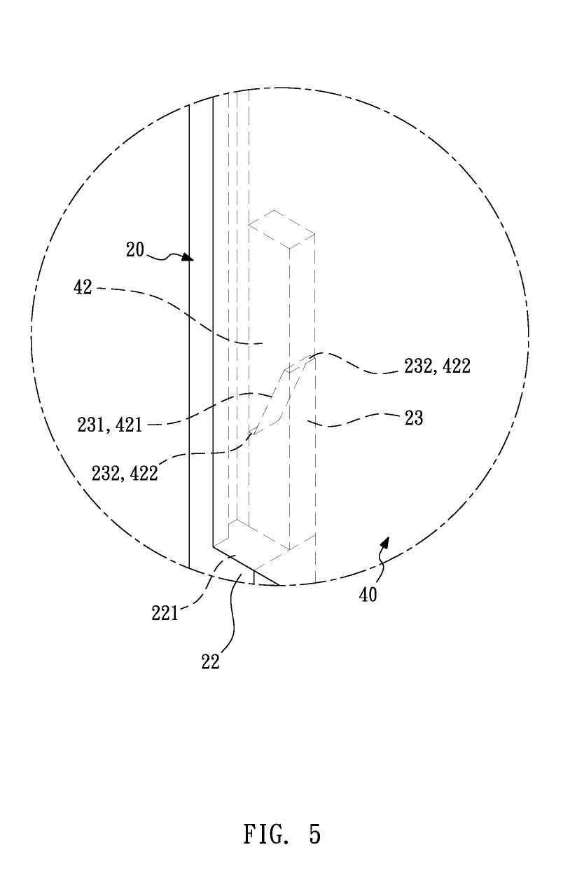

Two side boards 40 are provided with a protrusive strip 41 on two ends thereof, respectively, while a held block 42 with a bevel 421 thereon is fixed on a lateral side of the bottom end of the protrusive strip 41. When the active board 30 is at the unfolded position, the two protrusive strips 41 of the side boards 40 slide into the rails 13, 21 of the front and rear boards 10, 20, respectively, whereby the held blocks 42 are held by the supporters 15, 23, and the bottom edges of the side boards 40 are held by the holding surfaces 141, 221 of the feet 14, 22. Especially, as shown in FIG. 4 and FIG. 5, the side boards 40 are coupled with the front board 10 and the rear board 20 by corresponding concave and convex structures; as a result, the side boards 40 are slidingly disposed between the front board 10 and the rear board 20 by the bevel 421 contacting the bevel 231, whereby the top end of the two side boards 40 are kept at almost the same height as the top end of the front board 10 and the rear board 20. In addition, the bevels 231, 421 are provided with a plane 232, 422 on both the upper end and the lower end thereof, respectively, providing a positioning function between the bevels 231, 421 contacting with each other. For the clearness and conciseness of the drawing, only the contact relationship between the side board 40 and the rear board 20 is offered in the figures, while the contact relationship between the side board 40 and the front board 10 is identical.

The top board 50 is installed on the top ends of the front board 10, the rear board 20, and the two side boards 40 when the active boards 30 are at the unfolded position. Therein, plural connecting parts 51 are disposed along two edges of the bottom surface of the top board 50, while each connecting part 51 is provided with a positioning hole 52. The upper edges of the front board 10 and the rear board 20 are provided with plural through holes 16, 24 for correspondingly coupling the positioning holes 52 by fixing members 53.

The present invention further comprises a bottom board 60 moveably disposed between the two active boards 30, especially disposed in the back of the two short doors 12, whereby a space is formed by the front board 10, the rear board 20, and the top board 50 for placing things for storage. The method of disposing the bottom board 60 is not limited to specific measures; for example, the bottom board 60 can be held on inner surfaces of the front board 10 and the rear board 20 by use of plural positioning members. Furthermore, a middle board 70 is moveably disposed in the upper space of the bottom board 60 to partition such space into another compartment for placing goods.

Also, the present invention further comprises two side bottom boards 80 moveably disposed between the active boards 30 and the side boards 40, especially disposed in the back of the two side doors 11. Each of the upper spaces of the two side bottom board 80 is moveably provided with a side middle board 90, respectively, to partition such space into another compartment for placing goods. Therein, the side bottom boards 80, the side middle boards 90, and the middle board 70 are allowed to be disposed in a manner identical to the manner of the bottom board 60 being disposed.

Referring to FIG. 4 and FIG. 5, each of the side board 40 is slidingly disposed between the front board 10 and the rear board 20, with the held block 42 contacting the supporter 23 by the bevel 421 contacting the bevel 231; therefore, the top end of the two side boards 40, after being installed, are kept at almost the same height as the top end of the front board 10 and the rear board 20. Also, the bottom edges of the side boards 40 are held by the holding surfaces 221 of the feet 22, thereby maintaining the structural strength thereof.

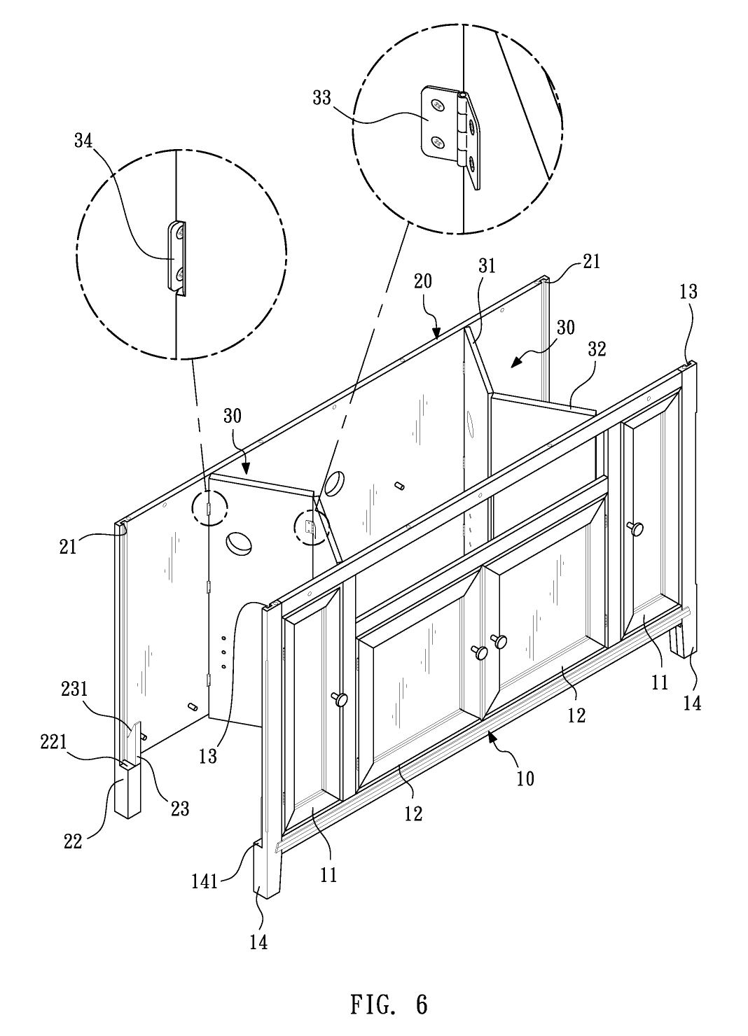

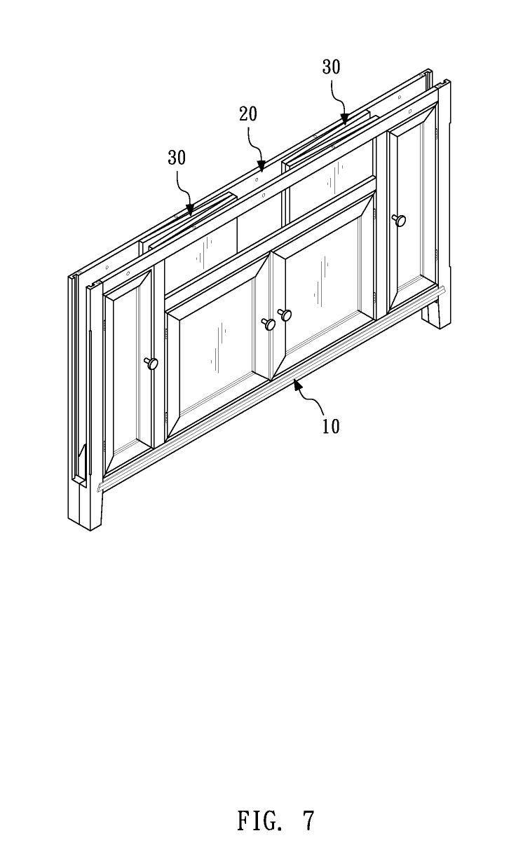

Referring to FIG. 6 and FIG. 7, when the top board 50, the side boards 40, the bottom board 60, the middle board 70, the side bottom boards 80, and the side middle boards 90 are detached from the front board 10 and the rear board 20, by use of the hinges 33 between the first panels 31 and the second panels 32, and the hinges 34 between the active boards 30 and the front board 10 and the rear board 20, the active boards 30 are allowed to be folded at the folded position. Thereby, the volume of the television cabinet 100 is minimized for lowering the cost and the inconvenience of transportation.

With the same structures, when the front board 10 and the rear board 20 are at the unfolded position, the top board 50, the side boards 40, the bottom board 60, the middle board 70, the side bottom boards 80, and the side middle boards 90 are only needed to be coupled to the original positions, respectively, for restoring the present invention to the unfolded position. As a result, the present invention is easily assembled.

Although particular embodiments of the invention have been described in detail for purposes of illustration, various modifications and enhancements may be made without departing from the spirit and scope of the invention. Accordingly, the invention is not to be limited except as by the appended claims.

What is claimed is:

1. A television cabinet, comprising
a front board;
a rear board;
at least two active boards, hinged between the front board and the rear board, while each of the active boards comprises a first panel and a second panel hinged together, for enabling the front board and the rear board to move between a folded position and an unfolded position;
two side boards, slidingly disposed between the front board and the rear board at the unfolded position; and
a top board, combined to the front board, the rear board, and the two side boards as a plane on top at the unfolded position.

2. The television cabinet of claim 1, wherein the front board comprises plural doors capable of open or close against the front board.

3. The television cabinet of claim 2, wherein the doors comprise two side doors and two short doors disposed between the two side doors.

4. The television cabinet of claim 1, wherein the active boards are hinged to the front board and the rear board by plural hinges.

5. The television cabinet of claim 1, wherein the first panel and the second panel are hinged together by plural hinges.

6. The television cabinet of claim 1, wherein a bottom board is moveably disposed between the two active boards, and a middle board is moveably disposed in the upper space of the bottom board.

7. The television cabinet of claim 1, wherein at least a side bottom board is moveably disposed between the active board and the side board.

8. The television cabinet of claim 7, wherein a side middle board is moveably disposed in the upper space of the side bottom board.

9. The television cabinet of claim 1, wherein the two side boards are slidingly disposed between the front board and the rear board, with corresponding concave and convex structures provided thereon for coupling the front board and the rear board.

10. The television cabinet of claim 9, wherein two ends of the side board are provided with a protrusive strip, respectively, and two ends of both the front board and the rear board are provided with a rail corresponding to the protrusive strip, respectively, for the protrusive strip to be slidingly disposed in the rail.

11. The television cabinet of claim 10, wherein a held block is fixed on a lateral side adjacent to the protrusive strip, while a supporter is fixed on a lateral side adjacent to the rail for holding the held block.

12. The television cabinet of claim 11, wherein the held block and the supporter are provided with a bevel, respectively, for contacting each other.

13. The television cabinet of claim 12, wherein the bevel is provided with a plane on an upper end and a lower end thereof, respectively.

14. The television cabinet of claim 13, wherein a foot is disposed on a lower distal end of the rail, while a holding surface is disposed on the foot for holding the bottom edge of the side board.

15. The television cabinet of claim 1, wherein plural connecting parts are disposed along two edges of the bottom surface of the top board for connecting with the inner side of the front board and the rear board, respectively, while each connecting part is provided with a positioning hole, and plural through holes corresponding to the positioning holes are disposed on the front board and the rear board, respectively, while a fixing member is inserted through each of the corresponding positioning hole and through hole.
